(19) United States
(12) Patent Application Publication
(10) Pub. No.: US 2004/0196061 A1
(43) Pub. Date: Oct. 7, 2004

(54) Socket or adapter device for semiconductor devices, method for testing semiconductor devices, and system comprising at least one socket or adapter device

(75) Inventor: Holger Hoppe, Mering (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 10/753,075

(22) Filed: Jan. 8, 2004

(30) Foreign Application Priority Data
Jan. 9, 2003 (DE) 103 00 532.3

(51) Int. Cl. G01R 31/26

(52) U.S. Cl. 324/765

(57) ABSTRACT

The invention relates to a method for testing semiconductor devices, to a system including at least one socket or adapter device, and to a socket or adapter device, in particular for semiconductor devices, including at least one connection pin which is designed to be adapted to be connected to a corresponding contact device of a device, wherein the connection pin is designed such that it can be connected to the contact device by surface mounting, in particular by solderless surface mounting.

### CLAIM FOR PRIORITY

This application claims the benefit of priority to German Application No. 103 00 532.3, filed in the German language on Jan. 9, 2003, the contents of which are hereby incorporated by reference.

### TECHNICAL FIELD OF THE INVENTION

The invention relates to a socket or adapter device, in particular for semiconductor devices, a method for testing semiconductor devices, and a system comprising at least one socket or adapter device.

### BACKGROUND OF THE INVENTION

Semiconductor devices, e.g. appropriate, integrated (analog or digital) computing circuits, semiconductor memory devices such as functional memory devices (PLAs, PALs, etc.) and table memory devices (e.g. ROMs or RAMs, in particular SRAMs and DRAMs), etc. are subject to comprehensive tests in the course of the manufacturing process.

For the common manufacturing of a plurality of (in general identical) semiconductor devices, a so-called wafer (i.e. a thin disc consisting of monocrystalline silicon) is used.

The wafer is processed appropriately (e.g. subject to a plurality of coating, exposure, etching, diffusion and implantation process steps, etc.), and subsequently e.g. sawn apart (or e.g. scratched and broken), so that the individual devices are then available.

After the sawing apart of the wafer, the devices—which are then available individually—are loaded each individually into special housings or packages, respectively (e.g. so-called TSOP or FBGA housings, etc.), and are then—for performing various testing methods—transported further to an appropriate testing station (or successively to a plurality of different testing stations).

At the respective testing station, individual devices available in the above-mentioned housings each are loaded into a corresponding adapter or socket, respectively, that is connected with a corresponding testing apparatus, and subsequently the device available in the respective housing is tested.

The testing station may, for instance, be a so-called burn-in testing station where a so-called burn-in test is performed, i.e. a test under extreme conditions (e.g. high temperature, for instance over 80° C. or 100° C., increased operating voltage, etc.).

At the burn-in testing station, a plurality of (e.g. special burn-in) sockets or adapters, respectively, is conventionally provided, into each of which a device to be tested is loaded.

The burn-in sockets (e.g. corresponding FBGA burn-in sockets) each are connected by means of appropriate soldering connections to a corresponding test circuit board which is connected with a corresponding testing apparatus.

This way, a plurality of—e.g. more than 100 or more than 200—devices can be tested simultaneously at the burn-in testing station by one and the same testing apparatus.

Burn-in sockets or adapters, respectively, are relatively expensive and relatively susceptible to faults (caused, for instance, by pollution, tin-lead-migration from the package soldering ball to the socket contact, etc).

When a faulty socket or adapter is to be exchanged on the test circuit board and to be replaced by a faultless socket or adapter, the corresponding faulty socket or adapter conventionally will have to be removed from the test circuit board by means of an appropriate unsoldering process, and then the corresponding replacement socket or replacement adapter will have to be soldered into the corresponding test circuit board.

This procedure is relatively time-consuming.

Moreover, there is the risk that the circuit board will be overheated and damaged or destroyed, respectively, in the course of the socket or adapter exchange procedure.

This is because the individual socket or adapter pins soldered into corresponding test circuit board bores at the respective socket or adapter only have a relatively small distance to one another (the distance between two socket or adapter pins positioned side by side may, for instance, be smaller than 1 mm, e.g. merely 0.8 mm).

The bores provided in the test circuit board and incorporating the pins therefore have relatively small dimensions (e.g. a diameter smaller than 0.5 mm, e.g. merely 0.3 mm).

For this reason, the solder remaining in the respective circuit board bores after the unsoldering of a faulty socket or adapter cannot be removed (or is difficult to remove, respectively).

Therefore, the circuit board has to be (locally) heated when the corresponding replacement socket is soldered in, so that the solder remaining in the respective bores can fuse, and the respective pins can then be introduced into the respective bores and be soldered therewith. During this procedure, overheating and damage or destruction, respectively, of the corresponding circuit board may occur.

### SUMMARY OF THE INVENTION

The invention to provide a novel socket or adapter device, in particular for semiconductor devices, a novel method for testing semiconductor devices, and a novel system, in particular a semiconductor device testing system, comprising at least one socket or adapter device.

In accordance with one embodiment of the invention, a socket or adapter device, in particular for semiconductor devices, is provided, comprising at least one connection pin which is designed such that it is adapted to be connected to a corresponding contact means of a device, wherein the connection pin is designed such that it can be connected to the contact means by surface mounting, in particular solderless surface mounting.

Preferably, at least one section of the connection pin has an arcuate or bent shape, e.g. substantially the shape of a semi-wave.

Advantageously, the connection pin is manufactured of a flexible or resilient material, in particular of an appropriate metal alloy, e.g. of a metal alloy comprising copper and/or beryllium.

In a preferred embodiment of the invention, there is provided—at least—one device (e.g. a corresponding screw connection (and/or a clamping connection, etc.)) by which the connection pin is pressed against the contact means, in particular against its contact surface.

Advantageously, the connection pin is connected to the contact device without soldering (preferably, corresponding further connection pins of the socket or adapter device are also connected to corresponding further contact device with-out soldering, in particular by means of surface mounting).

When, later on, a faulty socket device is to be removed from the device, in particular from the circuit board and is to be exchanged by a faultless socket device, unsoldering of the connection pin is not necessary (but merely a loosening of the above-mentioned screw connection (or clamping connection, etc.)).

An overheating of the corresponding circuit board can thus be avoided, and the socket device can be exchanged with relatively little time being needed.

### BRIEF DESCRIPTION OF THE DRAWINGS

In the following, the invention will be explained in detail with reference to the drawings, in which:

FIG. 1 shows stations passed through by corresponding semiconductor devices during the manufacturing of semiconductor devices.

FIG. 2 shows a side view of a socket used with the burn-in testing system illustrated in FIG. 1.

FIG. 3 shows a bottom view of the socket illustrated in FIG. 2.

FIG. 4 shows a side view of a section of the circuit board illustrated in FIG. 1, and of a section of the socket illustrated in FIGS. 1, 2, and 3, with a connection pin contacting a circuit board contact.

FIG. 5a shows a side view of the socket bottom and of the connection pin in accordance with a first embodiment of the invention.

FIG. 5b shows a side view of the socket bottom, and of a connection pin in accordance with an alternative, second embodiment of the invention.

FIG. 5c shows a side view of the socket bottom, and of a connection pin in accordance with a further alternative, third embodiment of the invention.

### DETAILED DESCRIPTION OF THE IVENTION

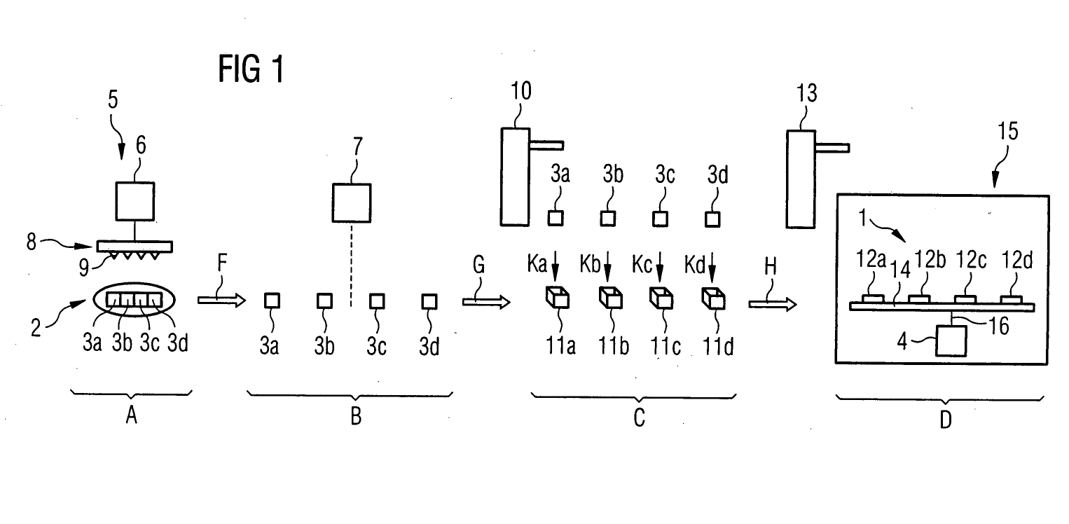

FIG. 1 schematically shows some (out of a plurality of further, not illustrated) stations A, B, C, D passed through by corresponding semiconductor devices 3a, 3b, 3c, 3d during the manufacturing of semiconductor devices 3a, 3b, 3c, 3d.

At station A, semiconductor devices 3a, 3b, 3c, 3d that are still available on a silicon disc or a wafer, 2, respectively, are subject to one or a plurality of testing methods by means of a testing system 5.

Before that, the wafer 2 had been subject, at stations not shown here and preceding the stations A, B, C, D illustrated in FIG. 1, to appropriate, conventional coating, exposure, etching, diffusion and implantation process steps.

The semiconductor devices 3a, 3b, 3c, 3d may, for instance, be appropriate, integrated (analog or digital) computing circuits, or semiconductor memory devices such as functional memory devices (PLAs, PALs, etc.) or table memory devices (e.g. ROMs or RAMs), in particular SRAMs and DRAMs (here e.g. DRAMs (Dynamic Random Access Memories or dynamic read-write memories, respectively) with double data rate (DDR-DRAMs=Double Data Rate DRAMs), advantageously High-Speed DDR-DRAMs).

The testing signals required at station A for testing the semiconductor devices 3a, 3b, 3c, 3d on the wafer 2 are generated by a testing apparatus 6 and are, by means of a semi-conductor device probe card 8 (more exactly: by means of appropriate contact needles 9 provided on the probe card 8), applied to corresponding pads of the semiconductor devices 3a, 3b, 3c, 3.

When the testing method(s) has (have) been finished successfully, the wafer 2 is transported further (in a fully automated manner) to the following station B (cf. Arrow F) and is there, by means of an appropriate machine 7, sawn apart (or e.g. scratched and broken), so that the individual semi-conductor devices 3a, 3b, 3c, 3d are then available.

After sawing apart the wafer 2 at station B, the devices 3a, 3b, 3c, 3d are (again in a fully automated manner, e.g. by means of an appropriate conveying machine) transported further to the following station C (here: a loading station C) (e.g. directly (or individually, respectively), or alternatively e.g. by means of an appropriate tray) (cf. Arrow G).

At the loading station C, the devices 3a, 3b, 3c, 3d are—individually each—loaded in a fully automated manner by means of an appropriate machine 10 (loading machine) into corresponding housings 11a, 11b, 11c, 11d or packages, respectively (cf. Arrows Kₐ, K_{b}, K_{c}, K_{d}), and the housings 11a, 11b, 11c, 11d are then—in a manner known per se—closed, so that corresponding semiconductor device contacts (provided, for instance, at the bottom of the semiconductor devices 3a, 3b, 3c, 3d) contact corresponding housing contacts (provided, for instance, at the top of the respective housings 11a, 11b, 11c, 11d).

As housings 11a, 11b, 11c, 11d, conventional TSOP housings may, for instance, be used, or e.g. conventional FBGA housings, etc.

Next, the housings 11a, 11b, 11c, 11d are—together with the semiconductor devices 3a, 3b, 3c, 3d—(again in a fully automated manner, e.g. by means of an appropriate conveying machine) transported further to a further station D, e.g. a testing station (cf. Arrow H), or successively to a plurality of different further stations, in particular testing stations (not illustrated).

Station D (or one or a plurality of the above-mentioned, not illustrated, further stations) may e.g. be a so-called burn-in station, in particular a burn-in testing station.

At station D, the housings 11a, 11b, 11c, 11d are loaded by means of an appropriate machine (e.g. a further loading machine 13, or the above-mentioned conveying machine) into corresponding sockets or adapters 12a, 12b, 12c, 12d.

When the sockets or adapters 12a, 12b, 12c, 12d are then closed—in a manner known per se—, corresponding further contacts (provided e.g. at the bottom of the housings (or alternatively: at the bottom of the semiconductor devices 3a, 3b, 3c, 3d)) contact corresponding socket contacts (provided e.g. at the top of the respective socket or adapter 12a, 12b, 12c, 12d).

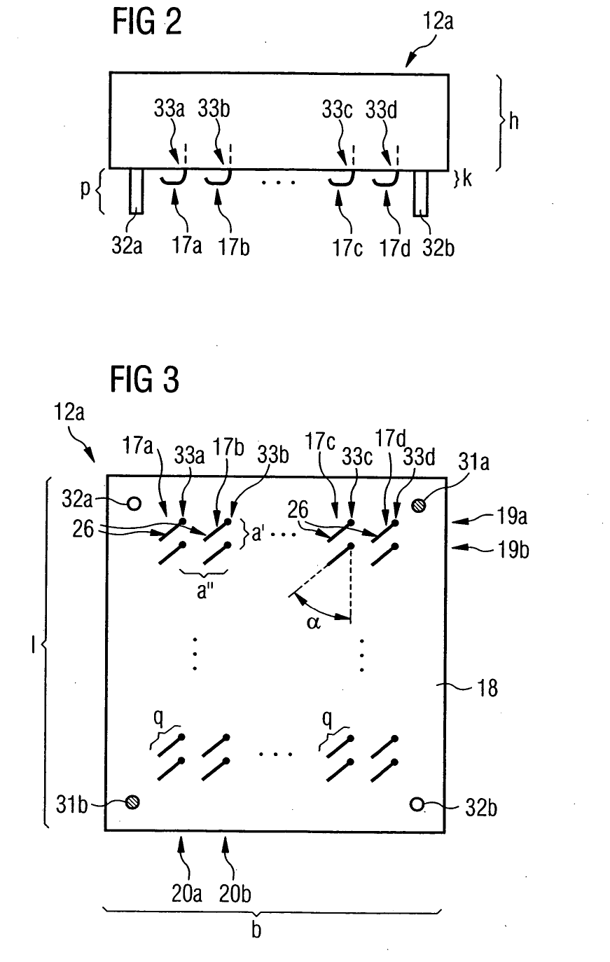

As will be explained more exactly in the following by making reference to FIGS. 2 and 3, a plurality of sockets or adapters 12a, 12b, 12c, 12d (e.g. more than 50, 100, or 200 sockets or adapters 12a, 12b, 12c, 12d) is connected at the testing station D to one and the same circuit board 14 (or to one and the same test circuit board 14, respectively).

The structure of the sockets or adapters 12a, 12b, 12c, 12d may be correspondingly similar to that of conventional burn-in sockets or burn-in adapters (e.g. corresponding TSOP or FBGA burn-in sockets), with the exception of, for instance, the manner—which will be explained in more detail further below—in which the sockets or adapters 12a, 12b, 12c, 12d are connected to the circuit board 14, or—in particular—the exact design of connection pins 17a, 17b, 17c, 17d provided at the sockets 12a, 12b, 12c, 12d.

The test circuit board 14 (and thus also the semiconductor devices 3a, 3b, 3c, 3d or the housings 11a, 11b, 11c, 11d loaded into the sockets or adapters 12a, 12b, 12c, 12d) is—as is illustrated in FIG. 1—by means of an appropriate machine (e.g. the above-mentioned conveying or loading machine 13, or a further machine) loaded into a “furnace” 15 adapted to be closed (or into a device 15 by which—for the above-mentioned semiconductor devices 3a, 3b, 3c, 3d—extreme conditions can be provided (e.g. high temperature, for instance over 70° C., 100° C., or 150° C., and/or increased device operating voltage, etc.)).

The test circuit board 14 is—in a correspondingly conventional manner—connected to a testing apparatus 4.

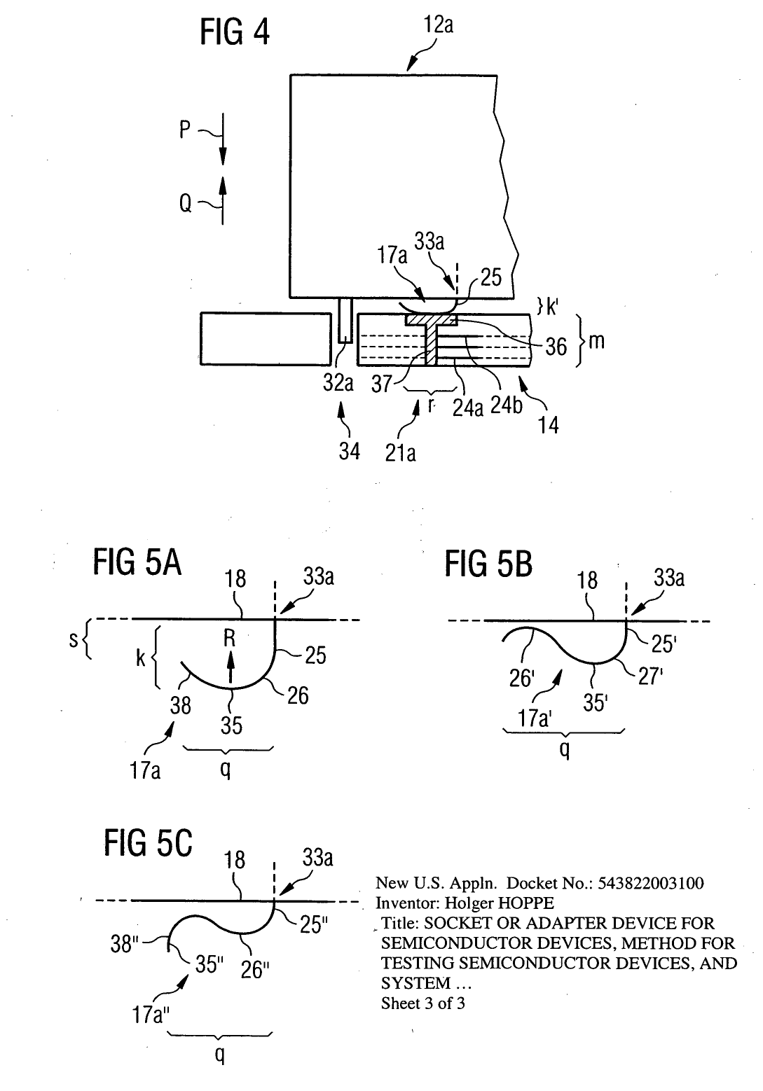

By this, it is achieved that test signals output by the testing apparatus 4 are, e.g. by means of corresponding lines 16, transferred to the test circuit board 14, and from there by means of corresponding circuit board contacts 21a, 21b, 21c, 21d—which are illustrated in detail in FIG. 4—and by connection pins 17a, 17b, 17c, 17d contacting same, to the sockets 12a, 12b, 12c, 12d.

From the sockets 12a, 12b, 12c, 12d, the corresponding test signals are then transferred via the above-mentioned socket contacts and the (further) housing contacts contacting same, to the housings 11a, 11b, 11c, 11d, and from there via the above-mentioned housing contacts and the semiconductor device contacts contacting same, to the semiconductor devices 3a, 3b, 3c, 3d to be tested.

The signals output at corresponding semiconductor device contacts in reaction to the test signals input are then correspondingly tapped by corresponding housing contacts (contacting same), and are supplied via the sockets 12a, 12b, 12c, 12d, the circuit board 14, and the lines 16 to the testing apparatus 4, where an evaluation of the corresponding signals can then take place.

Thus, the testing system 1—which i.a. comprises the testing apparatus 4, the circuit board 14, and the sockets 12a, 12b, 12c, 12d—can perform a corresponding, conventional testing method—e.g. a conventional burn-in test (or successively a plurality of such tests), in the course of which the functioning of the semiconductor devices 3a, 3b, 3c, 3d can, for instance, be checked (e.g. while or after the semi-conductor devices being subject for a relatively long time (e.g. for more than 30 minutes, or for more than e.g. 1 hour) to the above-mentioned extreme conditions in the above-mentioned “furnace” 15 or the device 15, respectively)).

Since—as explained above—more than 50, 100, or 200 sockets or adapters 12a, 12b, 12c, 12d are connected to the circuit board 14, the testing apparatus 4 illustrated in FIG. 1 can simultaneously test more than 50, 100, or 200 semiconductor devices 3a, 3b, 3c, 3d.

At station D, in particular in the furnace 15, in addition to the above-mentioned (test) circuit board 14, a plurality of further (test) circuit boards being of a structure corresponding to that of the test circuit board (14) and being connected to the testing apparatus 4 (or corresponding further testing apparatuses) may be provided (e.g. more than 20, or more than 30 or 50 (test) circuit boards), to which—in correspondence to the circuit board 14—more than 50, 100, or 200—sockets or adapters having a structure corresponding to that of the sockets or adapters 12a, 12b, 12d, 12e may be connected.

FIG. 2 illustrates a schematic side view of a socket or adapter 12a used with the testing system 1 shown in FIG. 1 (wherein one or a plurality of further, in particular all remaining, sockets or adapters 12b, 12c, 12d that are connected to the circuit board 14 (and possibly to the further circuit boards) may have a structure that is correspondingly identical to that of the socket or adapter 12a illustrated in FIG. 2).

As is illustrated in FIG. 2, the socket or adapter 12a, 12b, 12c, 12d comprises at its bottom 18 a plurality of connection pins 17a, 17b, 17c, 17d (e.g. more than 30, 40, or 60 pins, e.g. substantially corresponding to the number of semiconductor contacts (or housing contacts, respectively) provided or to be tested at the respective semiconductor devices 3a, 3b, 3c, 3d—or at the housings 11a, 11b, 11c, 11d, respectively).

FIG. 3 is a schematic bottom view of the socket 12a, 12b, 12c, 12d illustrated in FIG. 2.

The socket 12a, 12b, 12c, 12d may have a breadth b of e.g. between 10 mm and 4 cm, in particular of e.g. between 20 mm and 2 cm, and a corresponding length 1 (e.g. also of between 10 mm and 4 cm, in particular of e.g. between 20 mm and 2 cm), and—in accordance with FIG. 2—a height h of e.g. between 5 mm and 1 cm, in particular of between 10 mm and 2 cm.

Preferably, the socket 12a, 12b, 12c, 12d—or more exactly: the socket housing—is made of plastics.

As is illustrated in FIG. 3, the connection pins 17a, 17b, 17c, 17d at the socket bottom 18 are arranged substantially in the form of a plurality of pin rows 19a, 19b (e.g. in the form of more than 4, in particular more than 6 or 8 pin rows 19a, 19b), and in the form of a plurality of pin columns 20a, 20b (e.g. in the form of more than 4, in particular more than 6 or 8 pin columns 20a, 20b) (or, more exactly, the respective top pin sections 25 (cf. e.g. FIG. 4, and FIGS. 5a, 5b, 5c) or the pin connection points 33a, 33b, 33c, 33d (i.e. those points from which the connection pins 17a, 17b, 17c, 17d each project (perpendicularly) outwardly from the socket bottom 18) are arranged substantially in the form of different rows or columns 19a, 19b or 20a, 20b, respectively (i.e. each substantially—in the representation of FIG. 3—in different horizontal or vertical directions side by side (wherein always a plurality of the above-mentioned top pin sections 25 or pin connection points 33a, 33b, 33c, 33d are substantially arranged on one and the same straight line))).

The distance a″ between two adjacent pins 17a, 17b of the same row 19a, 19b (and/or the distance a′ between two adjacent pins of the same column 20a, 20b)—or, more exactly, the distance a′ or a″, respectively, between two top pin sections 25 of adjacent pins 17a, 17b or the distance a′ or a″, respectively, between two adjacent pin connection points 33a, 33b, 33c, 33d—may be relatively small (e.g. the distance a′ may be smaller than 1.5 mm or 1 mm, e.g. 0.8 mm or 0.65 mm, and the distance a″ may be smaller than 2 mm or 1.5 mm, e.g. 1 mm or 0.8 mm (wherein the distances a′ and a″ may be of different size, or alternatively also of equal size)).

In order to be able to provide on the—relatively small—bottom 18 of the socket 12a, 12b, 12c, 12d the above-mentioned—relatively large—number of connection pins 17a, 17b, 17c, 17d, the connection pins 17a, 17b, 17c, 17d are substantially arranged in equidistant distances to one another (e.g. with—approximately—the above-mentioned distances a′ in vertical direction (in the representation of FIG. 3), and with the above-mentioned distances a″ in horizontal direction (in the representation of FIG. 3)).

As results further from FIG. 3, the pin sections 26, each being adjacent to the top pin sections 25, of the connection pins 17a, 17b, 17c, 17d each are—viewed from the bottom—arranged obliquely with respect to the straight lines defined by the above-mentioned rows or columns, respectively (e.g. with an angle α of e.g. between 30° and 60°, in particular of 45°).

It is thus avoided that the pin sections 26 of the connection pins 17a, 17b, 17d, 17d extending in horizontal direction over a length q (e.g. a length q of between 2 mm and 0.3 mm, in particular of between 1.5 mm and 0.8 mm (cf. FIG. 3, and FIGS. 5a, 5b, 5c) get into contact with each other.

A plurality of, or all, respectively, connection pins 17a, 17b, 17c, 17d at the socket 12a each are of substantially identical design and each are formed of a resilient or elastic, electrically conductive material, e.g. a corresponding metal alloy, for instance copper-beryllium (CuBe).

The surface of the connection pins 17a, 17b, 17c, 17d may—so as to optimize the respective electrical contact to be produced (in particular with the corresponding circuit board contact 21a, 21b, 21c, 21d)—be provided with a corresponding metal coating, for instance be gold-plated in a conventional manner.

FIG. 4 is a schematic side view of a section of the circuit board 14 illustrated in FIG. 1, and a section of the socket or adapter 12a illustrated in FIGS. 1, 2, and 3.

The socket or adapter 12a comprises a plurality of (here: two) positioning pins 32a, 32b which extend e.g. from two areas of the socket bottom 18 being in the vicinity of two opposing corners of the socket or adapter 12a (cf. FIG. 3) in a substantially vertical direction downwards.

The positioning pins 32a, 32b may, for instance, be of cylinder-shaped design and may, for instance, have a length p that may e.g. be approximately equal to the thickness m of the circuit board 14, or e.g. somewhat smaller (e.g. a length p of less than 1.5 cm, in particular less than 1 cm).

As results from FIG. 4, the positioning pins 32a, 32b of the socket or adapter 12a each are introduced into a pertinent positioning bore 34 extending in transverse direction through the circuit board 14 (wherein the inside diameter of the positioning bore 34 is substantially as large—or somewhat smaller, respectively—as/than the outside diameter of the corresponding positioning pin 32a, 32b). It is thus achieved that, when the socket or adapter 12a is connected to the circuit board 14, the socket or adapter 12a is—with respect to the representation in FIG. 3 in horizontal and vertical direction—aligned correctly or is aligned correctly during mounting, respectively.

In accordance with FIG. 4, the connection pin 17a (more exactly: a contact area 35 at the bottom of the pin section 26) contacts from the top the—respectively pertinent—circuit board contact 21a provided on the circuit board 14 (more exactly: the top contact surface of a conductive contact layer, in particular a metal contact layer 36 provided at the top of the circuit board contact 21a and having—viewed from the top—e.g. a circular, oval, or rectangular cross-section).

The metal contact layer 36 has relatively small dimensions, e.g. a diameter r (or a length or breadth, respectively) which may e.g. be smaller than 1.5 mm, in particular smaller than 1 mm, 0.8 mm, or 0.6 mm (e.g. a diameter r which is approximately as large as, or somewhat smaller than, the length q—measured in horizontal direction—of the section 26 of the connection pin 25).

In a corresponding way as the connection pin 17a illustrated in FIG. 4, the remaining connection pins 17b, 17c, 17d of the socket or adapter 12a, and the connection pins of the remaining sockets or adapters 12b, 12c, 12d also contact—each from the top—the respectively pertinent circuit board contact 21b, 21c, 21d provided on the circuit board 14 (more exactly: the respective top contact surfaces of corresponding metal contact layers each provided at the top of the corresponding circuit board contacts 21b, 21c, 21d).

The remaining connection pins 17b, 17c, 17d provided at the socket 12a (and the remaining sockets)—not illustrated in FIG. 4—are of a correspondingly similar or identical structure and design as the connection pin 17a illustrated in FIG. 4.

As results from FIG. 4, the circuit board 14 is a so-called multilayer circuit board and is manufactured of a non-conductive basic material, e.g. of plastics. The circuit board lines 24a, 24b extend in a plurality of parallel planes and are connected to respectively corresponding circuit board contacts 21a, 21b, 21c, 21d (i.e. are connected with the respectively corresponding metal contact layer 36, e.g. by means of corresponding contact pins 37 extending in transverse direction through the circuit board and being conductively connected with the metal contact layer 36).

FIG. 5a shows a schematic side view of the connection pins 17a, 17b, 17c, 17d illustrated in FIGS. 2, 3, and 4. They have—in vertical direction—a maximum extension length k (or a distance k of the above-mentioned contact area 35 of the pin section 26 from the socket bottom 18) which may, for instance, be between 1.5 mm and 0.1 mm, in particular between 1 mm and 0.4 mm.

The connection pins 17a, 17b, 17c, 17d are fixed to the socket bottom 18 such that, when the respective socket 12a is mounted in the circuit board 14 (i.e. when the socket 12a is shifted downwards in vertical direction, cf. Arrow P in FIG. 4), the respective—bottom—pin sections 26 (or more exactly: their contact areas 35) each are positioned relatively exactly above the (here vertical) central axis of the respectively pertinent circuit board contact 21a, 21b, 21c, 21d (or its metal contact layer 36, respectively).

As results from FIG. 5a, the top pin section 25 of the respective connection pin 17a, 17b, 17c, 17d extends from the socket bottom 18 in a (first of all) substantially vertical direction to the socket bottom 18.

The pin section 26 which is adjacent to the top pin section 25 has—viewed from the side (cf. FIG. 5a)—an arcuate or curved, in particular a substantially wave-like shape (here: the shape of a semi or an almost semi-wave).

The corresponding connection pin 17a, 17b, 17c, 17d may, for instance, be manufactured by that—starting out from a first of all straight design of the connection pin 17a, 17b, 17c, 17d—the connection pin 17a, 17b, 17c, 17d is bent correspondingly, e.g. by the pin section 26 first of all being bent over to the left vis-à-vis the top pin section 25 (so that the above-mentioned arc or semi-wave shape results, wherein the end section 38 of the connection pin 17a should still have a residual distance s (e.g. of between 0.8 mm and 0.1 mm, in particular of between 0.6 mm and 0.2 mm) from the socket bottom 18).

Particularly preferably are the connection pins 17a, 17b, 17c, 17d manufactured—instead of by the above-described bending process—by means of a corresponding punching process (where the connection pins 17a, 17b, 17c, 17d are—in the above-described shape—punched out from a corresponding basic material).

When the respective socket 12a is mounted in the circuit board 14 (i.e. when the socket 12a is shifted in vertical direction to the bottom, cf. Arrow P in FIG. 4), the positioning pins 32a, 32b are inserted into the positioning bores 34, and the connection pins 17a, 17b, 17c, 17d (or more exactly: their contact areas 35) are pressed from the top against the respectively pertinent circuit board contacts 21a, 21b, 21c, 21d (more exactly: the top contact surfaces of the metal contact layers 36).

The connection pins 17a, 17b, 17c, 17d (or their respective top sections 25 (or the sections 26 adjacent thereto, respectively)) are bent towards the top (cf. e.g. Arrow R in FIG. 5a), or the connection pins 17a, 17b, 17c, 17d are slightly compressed, respectively (the pin extension length k—measured in vertical direction—or the distance k of the above-mentioned contact area 35 of the pin section 26 from the socket bottom 18 is then shortened to a pin extension length or a distance k′ (cf. FIG. 4) which may e.g. be between 1.0 mm and 0.05 mm, in particular between 0.7 mm and 0.2 mm).

Thus, a safe electrical contact between the connection pin 17a, 17b, 17c, 17d and the metal contact layer is provided (the connection pins 17a, 17b, 17c, 17d are thus connected to the circuit board contacts 21a, 21b, 21c, 21d by means of surface mounting (or compression mounting, respectively).

Therefore, a possible (additional) soldering of the connection pins 17a, 17b, 17c, 17d with the pertinent circuit board contacts 21a, 21b, 21c, 21d is not necessary.

In order to prevent that—due to forces occurring by the elastic deformation of the connection pins 17a, 17b, 17c, 17d—, after the shifting of the socket 12a in vertical direction downwards into the final position illustrated in FIG. 4, the socket 12a is again shifted upwards (cf. Arrow Q in FIG. 4), the socket 12a is fixed in the position illustrated in FIG. 4 (and is thus secured from a shifting in vertical direction).

This may, for instance, be effected by means of one or a plurality of screw connections (e.g. by means of one, tow, three, or four screws) by which the socket 12a is securely fixed to the circuit board 14, or the connection pins 17a, 17b, 17c, 17d are pressed against the pertinent circuit board contacts 21a, 21b, 21c, 21d, respectively.

For instance—as is shown in FIG. 3—the socket or adapter 12a may comprise a plurality of (here: two) bores 31a, 31b incorporating the respective screw of the respective screw connection, said bores being positioned e.g. at two areas of the socket bottom 18 positioned adjacent to two opposite corners of the socket or adapter 12a (in particular at corners opposite to the positioning pins 32a, 32b).

When a faulty socket 12a later (e.g. after a correspondingly long operation of the corresponding socket 12a) is to be removed from the circuit board 14 again and is to be exchanged by a faultless socket, the above-mentioned screw connection (or the above-mentioned screw connections) is/are simply loosened, whereafter the socket 12a can be dismounted from the circuit board 14 (e.g. by shifting the socket 12a in vertical direction upwards, cf. Arrow Q in FIG. 4)—with-out the circuit board contacts 21a, 21b, 21c, 21d or the connection pins 17a, 17b, 17c, 17d, respectively, having to be unsoldered.

FIG. 5b and FIG. 5c each show a schematic side view of the socket bottom 18, and of a connection pin 17a′ and 17a″ in accordance with alternative embodiments of the invention.

With the connection pin 17a′ illustrated in FIG. 5b, the pin section 26′ adjacent to the top pin section 25′ has—viewed from the side—(as with the connection pin 17a) a curved, in particular substantially wave-like shape (here: the shape of a complete or an—almost—complete wave). The contact area 35′ of the connection pin 17a′ contacting the corresponding circuit board contact 21a after the mounting of the socket 12a is positioned at the bottom of the partial section 27′ of the pin section 26′, said partial section 27′ being directly adjacent to the top pin section 25′ (and forming a semi-wave).

As is illustrated in FIG. 5c, with the connection pin 17a″ the pin section 26″ adjacent to the top pin section 25″ has—viewed from the side (as with the connection pins 17a and 17a′) a curved, in particular a substantially wave-like shape (here: the shape of a—somewhat more than complete—wave). The contact area 35″ of the connection pin 17″ contacting the corresponding circuit board contact 21a after the mounting of the socket 12a is positioned at the bottom of the end section 38″ of the pin section 26″.

Alternatively, other—similar—forms of contact are also conceivable.

What is claimed is:

1. A socket or adapter device, comprising at least one connection pin, the connection pin configured to be connected to a corresponding contact device of a device, wherein
the connection pin is configured to be connected to the contact device by solderless surface mounting.

2. The socket or adapter device according to claim 1, wherein the socket or adapter device is a semiconductor device testing socket or a semiconductor device testing adapter, respectively, which is configured for testing a semiconductor device such that it can be loaded with a corresponding semiconductor device.

3. The socket or adapter device according to claim 2, wherein the socket or adapter device is a burn-in testing socket or a burn-in testing adapter, respectively, which is configured for performing a burn-in test and can be loaded with a corresponding semiconductor device.

4. The socket or adapter device according to claim 1, wherein the connection pin is made of a flexible or resilient material.

5. The socket or adapter device according to claim 4, wherein the metal alloy includes copper and/or beryllium.

6. The socket or adapter device according to claim 1, wherein at least one section of the connection pin has an arcuate or bent shape.

7. The socket or adapter device according to claim 1, wherein the device comprising the contact device is a circuit board configured to be connected to a testing apparatus.

8. The socket or adapter device according to claim 1, wherein the device comprising the contact device is a testing apparatus.

9. A system, comprising:
at least one socket or adapter device; and
at least one semiconductor device testing apparatus or at least one circuit board, wherein
the socket or adapter device comprises at least one connection pin which is configured to be connected to a corresponding contact device for connection to the testing apparatus or to the circuit board that can be connected with a testing apparatus, and
the connection pin is connected to the contact device by surface mounting.

10. The system according to claim 9, wherein the connection pin is connected to the contact device without soldering.

11. The system according to claim 9, wherein a device is provided such that the connection pin is pressed against the contact device.

12. The system according to claim 11, wherein the device is an appropriate screw connection.

13. The system according to claim 11, wherein the device is an appropriate clamping connection.

14. The system according to claim 10, wherein the socket or adapter device comprises a plurality of connection pins, each being connected to corresponding contact device, and wherein the connection pins each are connected to the respectively corresponding contact devices without soldering.

15. A method for testing semiconductor devices, comprising:
connecting a socket or adapter device to a testing system, wherein at least one connection pin is connected to a corresponding contact device;
loading the socket or adapter device with a semi-conductor device to be tested,
wherein the connection of the connection pin to the contact device is performed by solderless surface mounting.
